(19) United States
(12) Patent Application Publication
(10) Pub. No.: US 2024/0334835 A1
(43) Pub. Date: Oct. 3, 2024

(54) PIEZOELECTRIC DEVICE

(71) Applicant: Murata Manufacturing Co., Ltd., Nagaokakyo-shi (JP)

(72) Inventors: Makoto SAWAMURA, Nagaokakyo-shi (JP); Ryosuke NIWA, Nagaokakyo-shi (JP); Shinsuke IKEUCHI, Nagaokakyo-shi (JP)

(21) Appl. No.: 18/739,371

(22) Filed: Jun. 11, 2024

Related U.S. Application Data
(63) Continuation of application No. PCT/JP2022/033757, filed on Sep. 8, 2022.

(30) Foreign Application Priority Data
Jan. 18, 2022 (JP) 2022-005692

(51) Int. Cl. H10N 30/87; H10N 30/06; H10N 30/081; H10N 30/20

(52) U.S. Cl. CPC H10N 30/875; H10N 30/06; H10N 30/081; H10N 30/2047

(57) ABSTRACT

A piezoelectric device includes a base with a cavity and a vibration layer on an upper side of the base and including a fixed portion fixed to the base and a membrane portion extending from the fixed portion over the cavity, the vibration layer includes a lower electrode layer connected to the base, a piezoelectric layer on an upper side of the lower electrode layer, and an upper electrode layer on an upper side of the piezoelectric layer. The piezoelectric layer is between the upper and lower electrode layers in at least a portion of the membrane portion. A first pad electrode is on an upper side of the upper electrode layer, a second pad electrode is on the upper side of the lower electrode layer, and a first conductor layer is on the upper side and spaced away from at least one of the first and second pad electrodes.

### CROSS REFERENCE TO RELATED APPLICATIONS

This application claims the benefit of priority to Japanese Patent Application No. 2022-005692 filed on Jan. 18, 2022 and is a Continuation Application of PCT Application No. PCT/JP2022/033757 filed on Sep. 8, 2022. The entire contents of each application are hereby incorporated herein by reference.

### BACKGROUND OF THE INVENTION

### 1. Field of the Invention

The present invention relates to piezoelectric devices.

### 2. Description of the Related Art

An example of a piezoelectric device is disclosed in International Publication No. WO2021/153491A1. This piezoelectric device includes a base and a plurality of beam sections. The base has a cavity. Each of the beam sections includes a fixed end portion connected to the base and a tip end portion located on a side opposite to the fixed end portion. Each of the beam sections is a piezoelectric vibrating section. The piezoelectric vibrating section includes a piezoelectric layer, a first electrode layer, and a second electrode layer. The piezoelectric layer is between the first electrode layer and the second electrode layer in the up-down direction. When a voltage is applied between the first electrode layer and the second electrode layer, the piezoelectric layer deforms, and the piezoelectric vibrating section vibrates.

### SUMMARY OF THE INVENTION

To apply a voltage between the first electrode layer which is an upper electrode and the second electrode layer which is a lower electrode, electrical connection from the outside to the piezoelectric device is necessary. Pad electrodes for this electrical connection are provided somewhere. Typically, the pad electrodes are provided on the upper surface of a fixed end portion. To form pad electrodes, for example, a method called “lift-off” is used. Specifically, a resist film is formed so as to cover the regions other than the regions where the pad electrodes are to be formed on the target surface, and a metal material is vapor-deposited so as to cover both the regions with the resist film and the regions without the resist film. A metal film is formed by this vapor deposition. After that, the target surface is immersed into an agent capable of dissolving the resist film, in other words, a so-called stripping liquid, to dissolve the resist film. With this step, in the regions where the metal film formed is present so as to overlie the resist film, the metal film is peeled off along with the dissolution of the resist film. However, in the regions where the resist film is not present and the metal film is directly attached to the target surface, the metal film is not peeled off and remains. Thus, a structure in which the metal film remains in only desired regions is formed. Such a method is referred to as a lift-off process.

To dissolve the resist film with a stripping liquid, the stripping liquid needs to make contact with the resist film. However, after the metal film is actually formed by vapor deposition, a major portion of the resist film is covered with the metal film, and thus the stripping liquid does not directly make contact with the resist film. The places where the resist film can make contact with the stripping liquid are the side surfaces of the steps at the boundaries between the regions covered with the resist film and the regions not covered with the resist film. Since the metal film formed by vapor deposition is interrupted on these side surfaces, the resist film is not covered with the metal film and is exposed. In these places, the stripping liquid makes contact with the resist film, and thus dissolution of the resist film is advanced. The stripping liquid further penetrates the resist film on the back side of the metal film through these steps, and the dissolution is further advanced.

The pad electrodes of the piezoelectric device are provided, for example, at two places on the upper surface of the fixed end portion. In the case in which these pad electrodes are formed by the lift-off process, most of the region of the target surface is covered with the resist film, and only small regions corresponding to the two pad electrodes are not covered with the resist film. The target surface in this state is immersed in a stripping liquid. In this state, the surfaces serving as the inlets for the penetration of the stripping liquid are only the side surfaces of the steps extending along the outlines of the pad electrodes. Hence, the penetration of the stripping liquid is difficult, and dissolution of the resist film takes time.

Example embodiments of the present invention provide piezoelectric devices in each of which a time necessary for a lift-off process for forming pad electrodes is short.

A piezoelectric device according to an example embodiment of the present invention is a piezoelectric device including a base with a cavity, and a vibration layer located on an upper side of the base. The vibration layer includes a fixed portion fixed to the base and a membrane portion continuously extending from the fixed portion and over the cavity. The vibration layer includes a lower electrode layer connected to the base, a piezoelectric layer located on an upper side of the lower electrode layer, and an upper electrode layer located on an upper side of the piezoelectric layer. The piezoelectric layer is between the upper electrode layer and the lower electrode layer in at least a portion of a region of the membrane portion. The piezoelectric device includes a first pad electrode located on an upper side of the upper electrode layer to be electrically connected to the upper electrode layer, a second pad electrode located on the upper side of the lower electrode layer to be electrically connected to the lower electrode layer without interposition of the piezoelectric layer, and a first conductor layer located on the upper side relative to the lower electrode layer and away from at least one of the first pad electrode and the second pad electrode.

With example embodiments of the present invention, the total area of the inlets for the penetration of a stripping liquid is large in the lift-off process for forming pad electrodes, which enables the dissolution of the resist film to be advanced efficiently. Accordingly, it is possible to provide piezoelectric devices in each of which the time necessary for the lift-off process for forming pad electrodes is short.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view of a piezoelectric device according to Example Embodiment 1 of the present invention.

FIG. 2 is a sectional view taken along line II-II in FIG. 1, viewed in the direction of the arrows.

FIG. 3 is a sectional view taken along line III-III in FIG. 1, viewed in the direction of the arrows.

FIG. 4 is an explanatory diagram illustrating the first step of a method of manufacturing the piezoelectric device according to Example Embodiment 1 of the present invention.

FIG. 5 is an explanatory diagram illustrating the second step of the method of manufacturing the piezoelectric device according to Example Embodiment 1 of the present invention.

FIG. 6 is an explanatory diagram illustrating the third step of the method of manufacturing the piezoelectric device according to Example Embodiment 1 of the present invention.

FIG. 7 is an explanatory diagram illustrating the fourth step of the method of manufacturing the piezoelectric device according to Example Embodiment 1 of the present invention.

FIG. 8 is an explanatory diagram illustrating the fifth step of the method of manufacturing the piezoelectric device according to Example Embodiment 1 of the present invention.

FIG. 9 is an explanatory diagram illustrating the sixth step of the method of manufacturing the piezoelectric device according to Example Embodiment 1 of the present invention.

FIG. 10 is an explanatory diagram illustrating the seventh step of the method of manufacturing the piezoelectric device according to Example Embodiment 1 of the present invention.

FIG. 11 is an explanatory diagram illustrating the eighth step of the method of manufacturing the piezoelectric device according to Example Embodiment 1 of the present invention.

FIG. 12 is an explanatory diagram illustrating the ninth step of the method of manufacturing the piezoelectric device according to Example Embodiment 1 of the present invention.

FIG. 13 is an explanatory diagram illustrating the tenth step of the method of manufacturing the piezoelectric device according to Example Embodiment 1 of the present invention.

FIG. 14 is an explanatory diagram illustrating the eleventh step of the method of manufacturing the piezoelectric device according to Example Embodiment 1 of the present invention.

FIG. 15 is an explanatory diagram illustrating the twelfth step of the method of manufacturing the piezoelectric device according to Example Embodiment 1 of the present invention.

FIG. 16 is an explanatory diagram illustrating the thirteenth step of the method of manufacturing the piezoelectric device according to Example Embodiment 1 of the present invention.

FIG. 17 is an explanatory diagram illustrating the fourteenth step of the method of manufacturing the piezoelectric device according to Example Embodiment 1 of the present invention.

FIG. 18 is an explanatory diagram illustrating the fifteenth step of the method of manufacturing the piezoelectric device according to Example Embodiment 1 of the present invention.

FIG. 19 is an explanatory diagram illustrating the sixteenth step of the method of manufacturing the piezoelectric device according to Example Embodiment 1 of the present invention.

FIG. 20 is an explanatory diagram illustrating the seventeenth step of the method of manufacturing the piezoelectric device according to Example Embodiment 1 of the present invention.

FIG. 21 is an explanatory diagram illustrating the eighteenth step of the method of manufacturing the piezoelectric device according to Example Embodiment 1 of the present invention.

FIG. 22 is an explanatory diagram illustrating the nineteenth step of the method of manufacturing the piezoelectric device according to Example Embodiment 1 of the present invention.

FIG. 23 is an explanatory diagram illustrating the twentieth step of the method of manufacturing the piezoelectric device according to Example Embodiment 1 of the present invention.

FIG. 24 is an explanatory diagram illustrating the twenty-first step of the method of manufacturing the piezoelectric device according to Example Embodiment 1 of the present invention.

FIG. 25 is an explanatory diagram illustrating the twenty-second step of the method of manufacturing the piezoelectric device according to Example Embodiment 1 of the present invention.

FIG. 26 is a plan view of a piezoelectric device according to Example Embodiment 2 of the present invention.

FIG. 27 is a plan view of a piezoelectric device according to Example Embodiment 3 of the present invention.

FIG. 28 is a sectional view taken along line XXVIII-XXVIII in FIG. 27, viewed in the direction of the arrows.

FIG. 29 is a sectional view taken along line XXIX-XXIX in FIG. 27, viewed in the direction of the arrows.

FIG. 30 is a plan view of a piezoelectric device according to Example Embodiment 4 of the present invention.

### DETAILED DESCRIPTION OF THE EXAMPLE EMBODIMENTS

### Example Embodiment 1

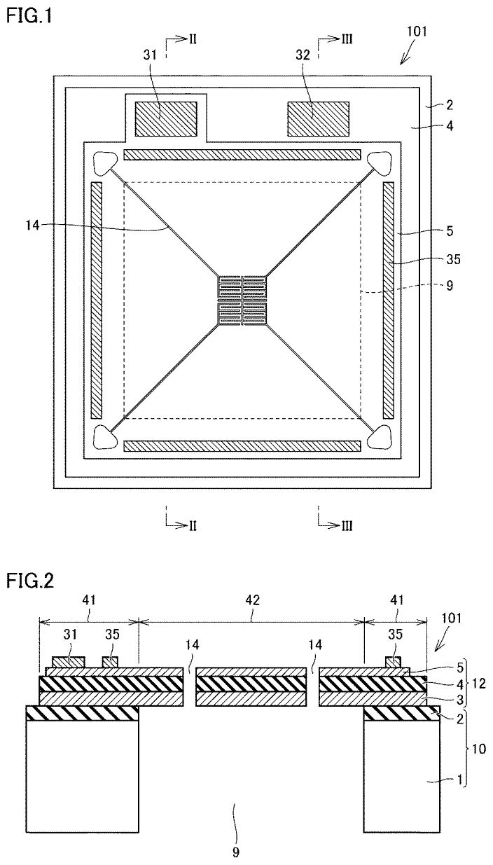

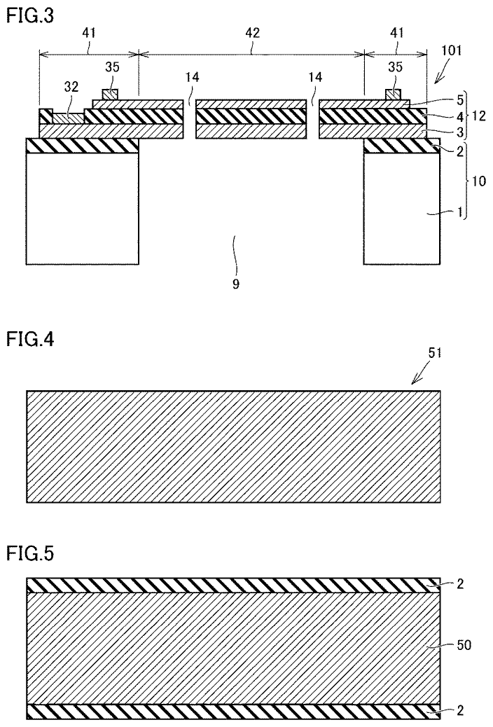

A piezoelectric device according to Example Embodiment 1 of the present invention will be described with reference to FIGS. 1 to 3. FIG. 1 is a plan view of a piezoelectric device 101. FIG. 2 is a sectional view taken along line II-II in FIG. 1, viewed in the direction of the arrows. FIG. 3 is a sectional view taken along line III-III in FIG. 1, viewed in the direction of the arrows.

The piezoelectric device 101 includes a base 10 having a cavity 9, and a vibration layer 12 located on the upper side of the base 10. The vibration layer 12 includes a fixed portion 41 fixed to the base 10, and a membrane portion 42 extending continuously from the fixed portion 41 and over the cavity 9. The vibration layer 12 includes a lower electrode layer 3 connected to the base 10, a piezoelectric layer 4 located on the upper side of the lower electrode layer 3, and an upper electrode layer 5 located on the upper side of the piezoelectric layer 4. The piezoelectric layer 4 is between the upper electrode layer 5 and the lower electrode layer 3 in at least a portion of the region of the membrane portion 42. The upper electrode layer 5 and the lower electrode layer 3 do not have the same size in plan view. The region that the upper electrode layer 5 covers may be a portion of the region that the lower electrode layer 3 covers. The piezoelectric device 101 includes a first pad electrode 31 located on the upper side of the upper electrode layer 5 so as to be electrically connected to the upper electrode layer 5, a second pad electrode 32 located on the upper side of the lower electrode layer 3 so as to be electrically connected to the lower electrode layer 3 without interposition of the piezoelectric layer 4, and a first conductor layer 35 located on the upper side relative to the lower electrode layer 3 and away from at least one of the first pad electrode 31 and the second pad electrode 32.

The base 10 includes a Si layer 1 and an oxide film 2 located on the Si layer 1. The oxide film 2 is a SiO₂ film. In FIG. 1, the cavity 9 is indicated by the dashed lines. The portion within the area of the cavity 9 in FIG. 1 is the membrane portion 42. Slits 14 illustrated in FIG. 1 connect the four corners and a center portion and form a certain pattern in the center portion. Although the slits 14 in the example illustrated in FIG. 1 include a complex shape in the center portion, this is a mere example. The shape of the slits 14 is not limited to the one illustrated in FIG. 1 and may be another shape. The lower electrode layer 3 is, for example, a Si layer. The piezoelectric layer 4 includes one of the piezoelectric materials described later.

A non-limiting example of a method of manufacturing the piezoelectric device 101 according to the present example embodiment will be described with reference to FIGS. 4 to 25. In an actual method that can be used, steps of the manufacturing method proceed with a collective board with a large size corresponding to a plurality of piezoelectric devices 101, and after a structure to some extent is built, the collective board is cut and divided into pieces with a size of an individual piezoelectric device 101. However, in the following description, steps will be described with the focus on one piece of a piezoelectric device 101, for the convenience of explanation.

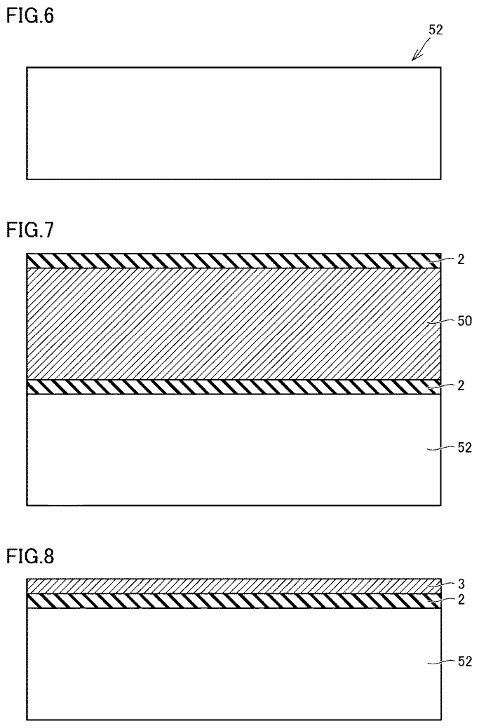

First, a Si substrate 51 is prepared as illustrated in FIG. 4. The Si substrate 51 is a low resistance substrate. The resistance of the Si substrate 51 is about 100 mΩcm or less, for example. Thermal oxide films are formed on respective sides of the Si substrate 51. With this step, a structure as illustrated in FIG. 5 is formed. In this structure, respective sides of the Si layer 50 are covered with the oxide films 2. Separately from this structure, a Si substrate 52 as illustrated in FIG. 6 is prepared. It is preferable that the Si substrate 52 have a high flatness. For example, it is preferable that the total thickness variation (TTV) of the Si substrate 52 be less than about 5 μm, for example.

As illustrated in FIG. 7, the Si substrate 52 and the structure obtained in FIG. 5 are stuck together. The method of sticking these two may be, for example, a method selected from direct bonding, plasma-activated bonding, atomic diffusion bonding, and the like.

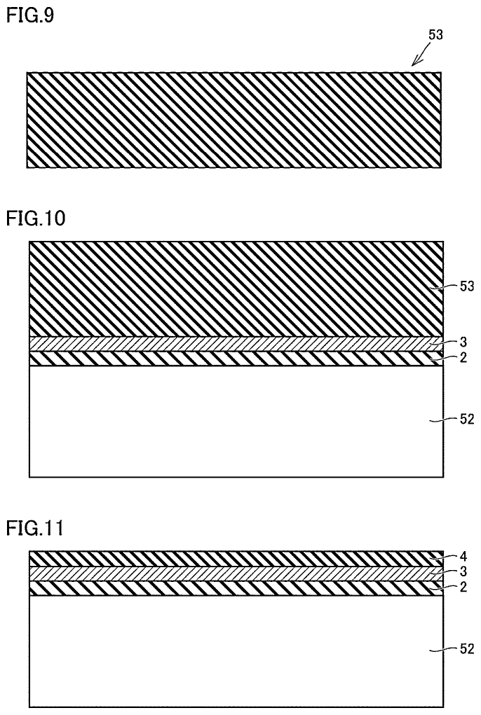

Next, the upper surface in FIG. 7 is processed by grinding or polishing. The polishing may be, for example, CMP. Thus, the lower electrode layer 3 is formed as illustrated in FIG. 8. In this step, a portion of the Si layer 50 that is left thin serves as the lower electrode layer 3. The thickness of the lower electrode layer 3 is, for example, about 1 μm or less. Separately, a piezoelectric substrate 53 as illustrated in FIG. 9 is prepared. The piezoelectric substrate 53 is a piezoelectric single crystal substrate. The material of the piezoelectric single crystal substrate mentioned here may be, for example, one selected from lithium tantalate (LiTaO₃) (which is also referred to as “LT”), lithium niobate (LiNbO₃) (which is also referred to as “LN”), quartz crystal, and the like.

As illustrated in FIG. 10, the structure illustrated in FIG. 8 and the piezoelectric substrate 53 illustrated in FIG. 9 are stuck together. Next, the upper surface in FIG. 10 is processed by grinding or polishing. The polishing may be, for example, chemical mechanical polishing (which is also referred to as “CMP”). The piezoelectric layer 4 is thus formed as illustrated in FIG. 11. A portion of the piezoelectric substrate 53 that is left thin serves as the piezoelectric layer 4. The thickness of the piezoelectric layer 4 is, for example, about 1 μm or less.

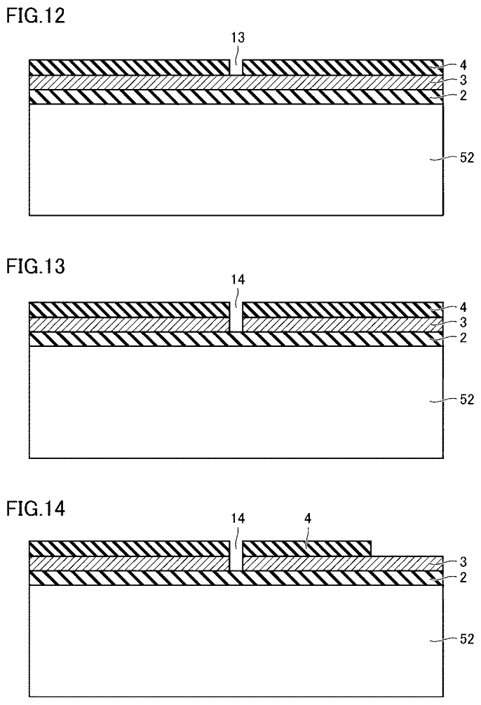

As illustrated in FIG. 12, slits 13 are formed in the piezoelectric layer 4. The slits 13 are formed to have the same pattern in plan view as the slits 14 illustrated in FIG. 1. The slits 13 can be formed by forming a resist pattern by photolithography, and then performing dry etching such as reactive ion etching (which is also referred to as “RIE”). Since the slits 13 actually include a complex pattern, their sectional view is not as simple as illustrated in FIG. 12. However, for the convenience of explanation, the slits 13 are simplified in the illustration here, and in FIG. 12, a slit 13 is illustrated at only one position at the center. The same applies to the following figures.

As illustrated in FIG. 13, the slit 13 is further dug down into the lower electrode layer 3 to form a slit 14. Also the slit 14 can be formed by forming a resist pattern by photolithography and then performing dry etching such as RIE.

Further, an engraved pattern is formed in the piezoelectric layer 4. Specifically, as illustrated in FIG. 14, part of the piezoelectric layer 4 is removed to partially expose the upper surface of the lower electrode layer 3. Next, as illustrated in FIG. 15, the upper electrode layer 5 is formed so as to cover a portion of the upper surface of the piezoelectric layer 4. The material of the upper electrode layer 5 is, for example, Pt. The upper electrode layer 5 may be formed by a lift-off process. Specifically, a metal film may be formed only in desired regions by forming a resist film that covers the entire surface, forming a resist pattern by photolithography, then forming a metal film that covers the entire surface by vapor deposition, and dissolving the resist pattern with a stripping liquid to peel off unnecessary portions of the metal film. The upper electrode layer 5 is not limited to a single layer structure including only Pt. For example, after an adhesion layer including Ti, Mo, Ni, or the like is formed, and then a Pt film may be formed on it. In other words, the upper electrode layer 5 may have a structure including two or more layers. Alternatively, the main material of the upper electrode layer 5 may be Au instead of Pt.

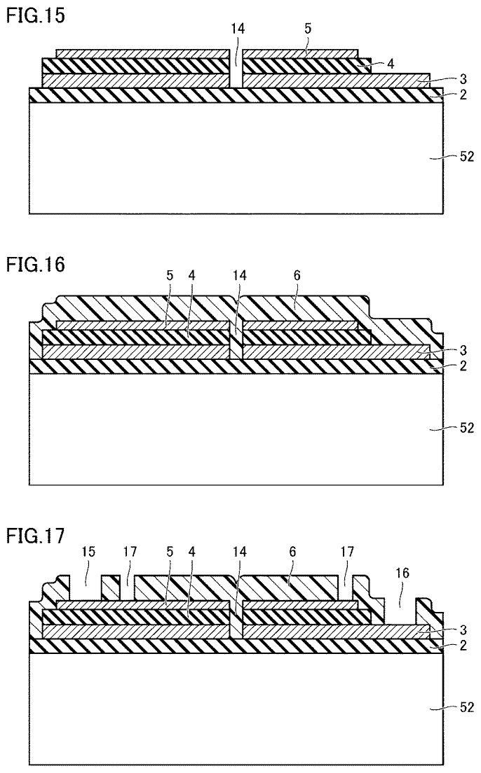

As illustrated in FIG. 16, a resist film 6 is formed to cover the entire surface. The resist film 6 is patterned as illustrated in FIG. 17. Thus, cavities 15, 16, and 17 are formed in the resist film 6. The cavity 15 corresponds to the region where the first pad electrode 31 is to be formed. The cavity 16 corresponds to the region where the second pad electrode 32 is to be formed. The cavity 16 is formed in the engraved pattern illustrated in FIG. 14. The cavities 17 each correspond to the region where the first conductor layer 35 is to be formed. The upper electrode layer 5 is exposed at the bottoms of the cavities 15 and 17. The lower electrode layer 3 is exposed at the bottom of the cavity 16.

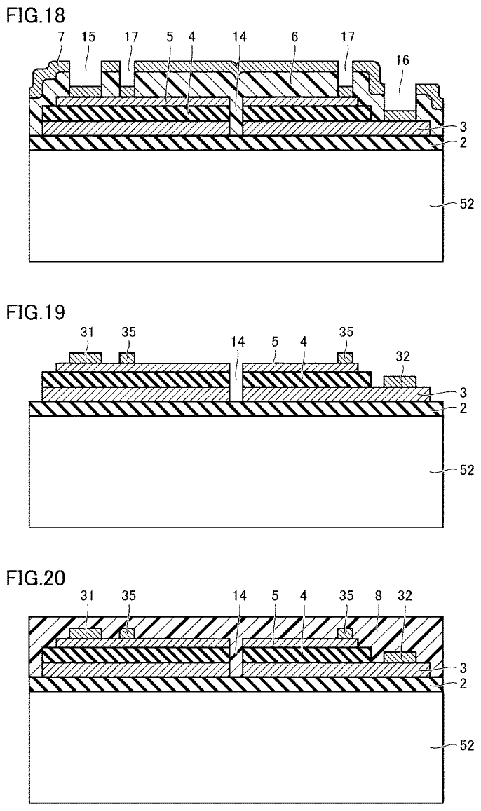

As illustrated in FIG. 18, a metal film 7 is formed by vapor deposition. The metal film 7 is formed to cover the upper surface of the resist film 6. In the cavities 15, 16, and 17, the side surfaces of the resist film 6 are not covered with the metal film 7 and are exposed. This structure is immersed in a stripping liquid and shook to dissolve the resist film 6. With this operation, the portions of the metal film 7 located on the resist film 6 are peeled off, and the other portions remain. As illustrated in FIG. 19, the first pad electrode 31, the second pad electrode 32, and the first conductor layer 35 are thus formed. All of the first pad electrode 31, the second pad electrode 32, and the first conductor layer 35 are the remaining portions of the metal film 7.

As can be seen from FIGS. 1 to 3, none of the sections across the membrane portion 42 includes the first pad electrode 31, the second pad electrode 32, and the first conductor layer 35. However, for the convenience of explanation, one sectional view is illustrated to include the first pad electrode 31, the second pad electrode 32, and the first conductor layer 35.

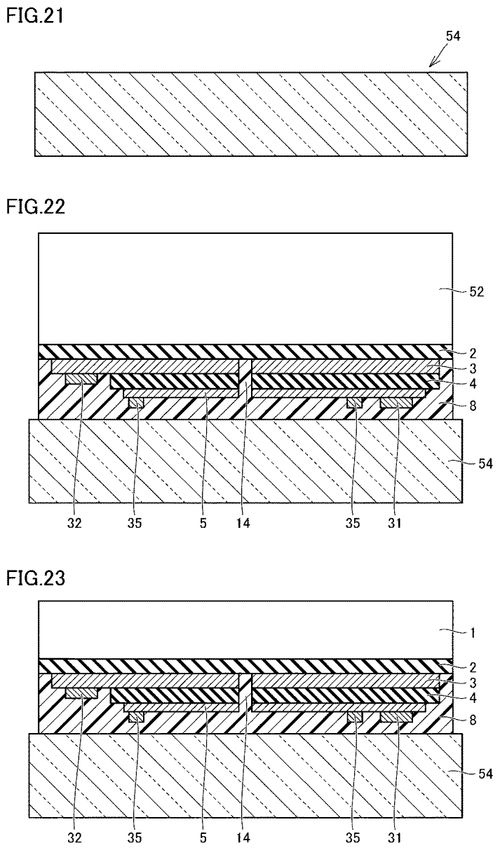

A resist film 8 is formed to cover the upper surface of the structure illustrated in FIG. 19. The structure illustrated in FIG. 20 is thus formed. The first pad electrode 31, the second pad electrode 32, and the first conductor layer 35 are covered with the resist film 8. When the resist film 8 is formed, it is preferable to perform the process at a high temperature of about 130° C. or more, for example, to prevent dripping. Separately, a support substrate 54 is prepared as illustrated in FIG. 21. The material of the support substrate 54 may be, for example, glass, Si, or the like. The structure illustrated in FIG. 20 and the support substrate 54 illustrated in FIG. 21 are stuck together. The sticking may be performed with a tape, a film, or the like. The structure illustrated in FIG. 22 is thus formed. The upper surface of this structure is processed by grinding or polishing. The polishing may be, for example, CMP. With this step, the Si substrate 52 is made thin to be the Si layer 1 as illustrated in FIG. 23. The thickness of the Si layer 1 is about 400 μm or less, for example.

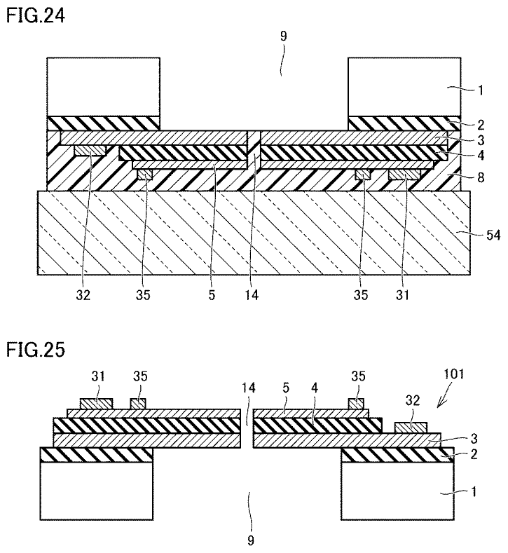

Next, a portion of the Si layer 1 and a portion of the oxide film 2 are removed to form the cavity 9 as illustrated in FIG. 24. Also the cavity 9 can be formed by forming a resist pattern on the Si layer 1 by photolithography and then performing dry etching such as RIE. By forming the cavity 9, the membrane portion 42 (see FIGS. 2 and 3) is formed.

The resist film 8 is dissolved with a chemical agent or the like. As a result, the support substrate 54 is peeled off. In addition, plasma ashing may be performed. The piezoelectric device 101 is thus formed as illustrated in FIG. 25. Although the piezoelectric device 101 illustrated in FIG. 25 is intended to be the same as the piezoelectric device illustrated in FIGS. 1 to 3, FIG. 25 is illustrated for the convenience of explanation such that one sectional view includes the first pad electrode 31, the second pad electrode 32, and the first conductor layer 35. Hence, FIG. 25 looks different from FIGS. 2 and 3.

Since the piezoelectric device 101 of the present example embodiment can use the manufacturing method as described above, large portions of the side surfaces of the resist film 6 are exposed in the lift-off process for forming the first pad electrode 31 and the second pad electrode 32 as illustrated in FIG. 18. In other words, the total area of the inlets for the penetration of the stripping liquid is large. Accordingly, the dissolution of the resist film can be efficiently advanced. As described above, as for the piezoelectric device of the present example embodiment, the time necessary for the lift-off process for forming the pad electrodes can be short. In addition, the yield can be improved.

As mentioned in the present example embodiment, it is preferable that the first conductor layer 35 be located outside the cavity 9 in plan view. Use of this configuration makes it possible to avoid the first conductor layer 35 affecting the vibration characteristics of the membrane portion 42 located inside the cavity 9.

As mentioned in the present example embodiment, it is preferable that the first pad electrode 31, the second pad electrode 32, and the first conductor layer 35 include the same kind of metal or a same metal. Use of this structure can reduce the number of steps in the production.

As mentioned in the present example embodiment, it is preferable that the first conductor layer 35 include a plurality of conductor layer elements located intermittently so as to surround the cavity 9 in plan view. As illustrated in FIG. 1, the first conductor layer 35 includes four conductor layer elements in a straight line shape. Each individual straight-line portion serves as one conductor layer element. The four straight-line shaped conductor layer elements have approximately a square shape as a whole. It can also be said that the first conductor layer 35 is located intermittently such that the square is interrupted at the four corners. As illustrated in FIG. 1, portions of the slits 14 may be present in the portions where the first conductor layer 35 is interrupted. Since the first conductor layer 35 includes the plurality of conductor layer elements located intermittently so as to surround the cavity 9 in plan view, the metal film 7, which is being peeled off, remains connected instead of quickly being apart during the lift-off process. In the lift-off process, the container in which the target object is immersed is shook to promote dissolution in some cases. This configuration enables the target object to be shook with the metal film 7, which is being peeled off, remaining connected. Since the structure is shook with the metal film 7, which is being peeled off, remaining connected, dissolution of the remaining resist film 6 can be promoted. Thus, the lift-off process can be advanced efficiently.

As mentioned in the present example embodiment, it is preferable that at least a portion of the first conductor layer 35 be located on the upper side of the upper electrode layer 5. Use of this configuration enables a voltage to be stably applied to the upper electrode layer 5 because the first conductor layer 35 can serve as a detour path for electric current when the voltage is applied to the upper electrode layer 5.

It is preferable that the first conductor layer 35 be thicker than the upper electrode layer 5. In the case in which the first conductor layer 35 is thick as mentioned above, the resistance of the first conductor layer 35 is low, and hence the first conductor layer 35 serves as a low-resistance detour path for electric current, which makes voltage application to the upper electrode layer 5 more stable.

### Example Embodiment 2

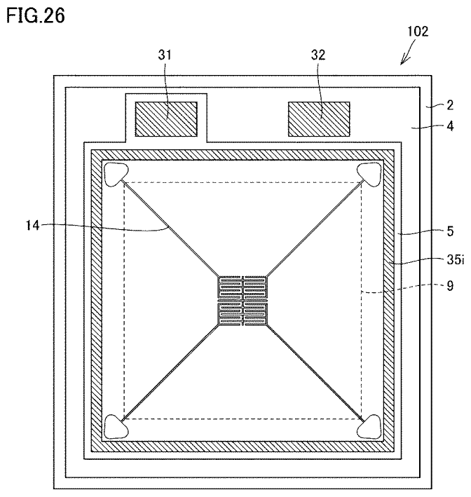

A piezoelectric device according to Example embodiment 2 of the present invention will be described with reference to FIG. 26. FIG. 26 is a plan view of a piezoelectric device 102 of the present example embodiment. Although the piezoelectric device 101 described in Example Embodiment 1 includes the first conductor layer 35 including the plurality of conductor layer elements located intermittently, the present example embodiment includes a first conductor layer 35i instead of the first conductor layer 35. The first conductor layer 35i has a loop shape surrounding a cavity 9 in plan view. The first conductor layer 35i has a continuous closed loop shape. The other configuration is the same as or similar to that described in Example Embodiment 1. Although the first conductor layer 35i has a square loop shape in the illustrated example, this is a mere example. The first conductor layer 35i may have a loop of a shape other than a square.

Also the present example embodiment provides the effects the same as or similar to those in Example Embodiment 1. In addition, since the first conductor layer 35i has a loop shape in the present example embodiment, the metal film 7 formed on the upper surface of the resist film 6 in the region inside the first conductor layer 35i is peeled off and apart as a separate small piece in the lift-off process. In the case in which the metal film 7 is partially peeled off and remains connected, there is a possibility that the metal film 7 being shook can collide with and damage other portions. In contrast, since the metal film 7 peeled off immediately moves away in the present example embodiment, it is possible to reduce the possibility that collisions of the metal film 7 due to shaking can cause flaws.

### Example Embodiment 3

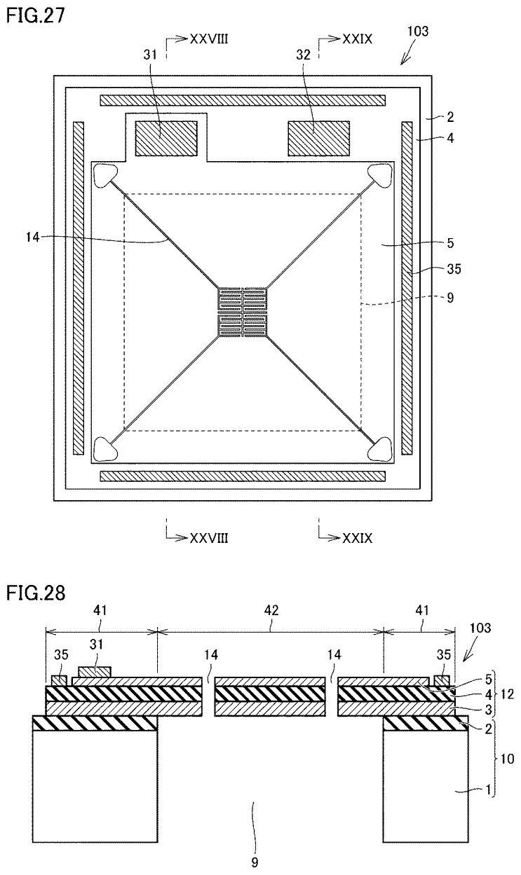

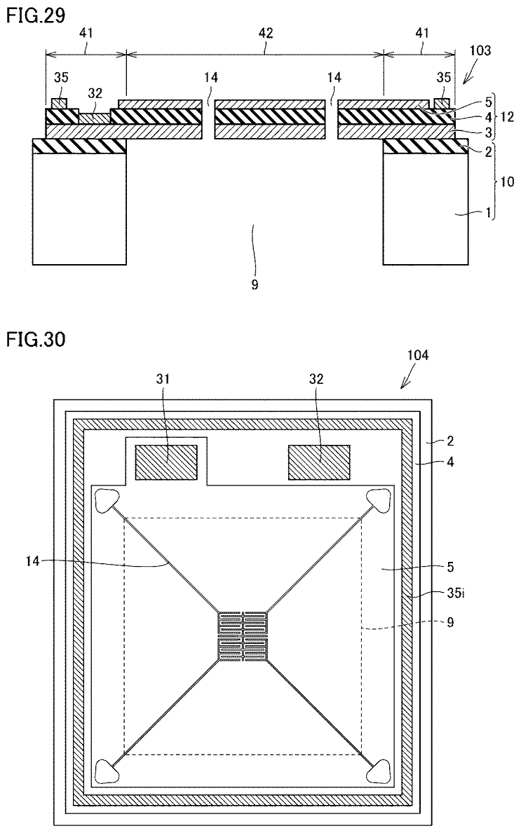

A piezoelectric device according to Example Embodiment 3 of the present invention will be described with reference to FIG. 27. FIG. 27 is a plan view of a piezoelectric device 103 of the present example embodiment. FIG. 28 is a sectional view taken along line XXVIII-XXVIII in FIG. 27, viewed in the direction of the arrows. FIG. 29 is a sectional view taken along line XXIX-XXIX in FIG. 27, viewed in the direction of the arrows. Although the first conductor layer 35 in Example Embodiment 1 is located on the upper surface of the upper electrode layer 5, a first conductor layer 35 in the present example embodiment is located at a position that is not on the upper surface of the upper electrode layer 5. The first conductor layer 35 is located outside the upper electrode layer 5 in plan view. The first conductor layer 35 is located on the upper surface of the piezoelectric layer 4 outside the upper electrode layer 5.

Also the present example embodiment provides the effects the same as or similar to those in Example Embodiment 1. In addition, in the present example embodiment, the layout of the first conductor layer 35 can be determined without a limitation of the size of the upper electrode layer 5, which increases the degree of freedom in design. The nonrestrictive layout of the first conductor layer 35 enables the area of the inlets for the penetration of a stripping liquid to be increased as necessary.

### Example Embodiment 4

A piezoelectric device according to Example Embodiment 4 of the present invention will be described with reference to FIG. 30. FIG. 30 is a plan view of a piezoelectric device 104 of the present example embodiment. Although Example Embodiment 3 has the first conductor layer 35 including the plurality of conductor layer elements located intermittently, the present example embodiment has a loop-shaped first conductor layer 35i. The loop-shaped first conductor layer 35i is located outside the upper electrode layer 5 in plan view.

The present example embodiment provides both the effects described in Example Embodiment 2 and the effects described in Example Embodiment 3.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A piezoelectric device comprising:
a base with a cavity; and
a vibration layer located on an upper side of the base; wherein
the vibration layer includes a fixed portion fixed to the base and a membrane portion continuously extending from the fixed portion and over the cavity;
the vibration layer includes a lower electrode layer connected to the base, a piezoelectric layer located on an upper side of the lower electrode layer, and an upper electrode layer located on an upper side of the piezoelectric layer;
the piezoelectric layer is between the upper electrode layer and the lower electrode layer in at least a portion of a region of the membrane portion; and
the piezoelectric device includes:
a first pad electrode located on an upper side of the upper electrode layer to be electrically connected to the upper electrode layer;
a second pad electrode located on the upper side of the lower electrode layer to be electrically connected to the lower electrode layer without interposition of the piezoelectric layer; and
a first conductor layer located on the upper side relative to the lower electrode layer and away from at least one of the first pad electrode and the second pad electrode.

2. The piezoelectric device according to claim 1, wherein in plan view, the first conductor layer is located outside the cavity.

3. The piezoelectric device according to claim 1, wherein the first pad electrode, the second pad electrode, and the first conductor layer include a same kind of metal.

4. The piezoelectric device according to claim 1, wherein in plan view, the first conductor layer includes a plurality of conductor layer elements located intermittently to surround the cavity.

5. The piezoelectric device according to claim 1, wherein in plan view, the first conductor layer has a loop shape surrounding the cavity.

6. The piezoelectric device according to claim 1, wherein at least a portion of the first conductor layer is located on the upper side of the upper electrode layer.

7. The piezoelectric device according to claim 6, wherein the first conductor layer is thicker than the upper electrode layer.

8. The piezoelectric device according to claim 1, wherein in plan view, the first conductor layer is located outside the upper electrode layer.

9. The piezoelectric device according to claim 1, wherein the upper electrode layer and the lower electrode layer do not have a same size in a plan view.

10. The piezoelectric device according to claim 1, wherein the base includes a Si layer and an oxide film on the Si layer.

11. The piezoelectric device according to claim 1, wherein slits are located in the base.

12. The piezoelectric device according to claim 11, wherein the slits extend from a center to corners of the base.

13. The piezoelectric device according to claim 1, wherein the lower electrode layer is a Si layer.

14. The piezoelectric device according to claim 5, wherein the loop shape is a square loop shape.

15. The piezoelectric device according to claim 5, wherein the loop shaped first conductor layer is located outside the upper electrode layer in plan view.

16. The piezoelectric device according to claim 4, wherein the plurality of conductor layer elements includes four conductor layer elements in a straight line shape.

17. The piezoelectric device according to claim 4, wherein the plurality of conductor layer elements includes four conductor layer elements in a straight line shape.

18. The piezoelectric device according to claim 17, wherein the four conductor layer elements have an approximately square shape as a whole.
